(19) United States
(12) Patent Application Publication
(10) Pub. No.: US 2022/0216362 A1
(43) Pub. Date: Jul. 7, 2022

(54) MANUFACTURING METHOD OF DISPLAY DEVICE

(71) Applicant: Innolux Corporation, Miao-Li County (TW)

(72) Inventors: Jia-Yuan Chen, Miao-Li County (TW); Tsung-Han Tsai, Miao-Li County (TW); Kuan-Feng Lee, Miao-Li County (TW)

(73) Assignee: Innolux Corporation, Miao-Li County (TW)

(21) Appl. No.: 17/546,018

(22) Filed: Dec. 8, 2021

(30) Foreign Application Priority Data
Jan. 5, 2021 (CN) 202110008132.9

(51) Int. Cl. H01L 33/00; H01L 27/15; H01L 33/24

(52) U.S. Cl. CPC H01L 33/005; H01L 33/24; H01L 27/156

(57) ABSTRACT

A manufacturing method of a display device includes the following steps. A substrate is provided. The substrate has a pixel region, and a driving circuit is disposed on the pixel region. A light emitting element is placed in the pixel region. An electric field is applied to align the light emitting element. The aligned light emitting element is electrically connected to the driving circuit. The substrate carrying the aligned light emitting element is cut into multiple sub-substrates. The manufacturing method of the display device in the embodiment of the disclosure may reduce the processing time or have a better processing sequence.

### CROSS-REFERENCE TO RELATED APPLICATION

This application claims the priority benefit of China application serial no. 202110008132.9, filed on Jan. 5, 2021. The entirety of the above-mentioned patent application is hereby incorporated by reference herein and made a part of this specification.

### BACKGROUND

### Technical Field

The disclosure relates to a manufacturing method of a display device, and more particularly, to a manufacturing method of a display device that may reduce processing time or have a better processing sequence.

### Description of Related Art

Display devices have been widely applied to electronic devices such as mobile phones, televisions, monitors, tablet computers, vehicle displays, wearable devices, and desktop computers. With the vigorous development of electronic devices, the requirements for the display quality of the display device also increase, so that display devices are constantly improving towards the display effect of high brightness, low energy consumption, high resolution, or high saturation. Meanwhile, the manufacturing methods of display devices are also constantly improving towards reduced processing time, reduced processing steps, or a better processing sequence.

### SUMMARY

The disclosure provides a manufacturing method of a display device, which may reduce processing time or have a better processing sequence.

According to embodiments of the disclosure, the manufacturing method of a display device includes the following steps. A substrate is provided. The substrate has a pixel region, and a driving circuit is disposed on the pixel region. A light emitting element is placed in the pixel region. An electric field is applied to align the light emitting element. The aligned light emitting element is electrically connected to the driving circuit. The substrate carrying the aligned light emitting element is cut into multiple sub-substrates.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1I are schematic top diagrams or schematic cross-sectional diagrams of a manufacturing method of a display device according to some embodiments of the disclosure.

FIG. 2A and FIG. 2B are respectively a schematic bottom diagram and a schematic cross-sectional diagram of a light emitting element according to some embodiments of the disclosure.

FIG. 2C and FIG. 2D are respectively a schematic top diagram and a schematic cross-sectional diagram of a light emitting element according to some embodiments of the disclosure.

FIG. 3A is a circuit diagram of a driving circuit of a display device according to some embodiments of the disclosure.

FIG. 3B is a circuit diagram of a driving circuit of a display device according to some embodiments of the disclosure.

FIG. 4A is a schematic diagram of a generating method of an AC voltage according to some embodiments of the disclosure.

FIG. 4B is a timing diagram of the generating method of an AC voltage of FIG. 4A.

FIG. 5A and FIG. 5B are schematic cross-sectional diagrams of part of a manufacturing method of a display device according to some embodiments of the disclosure.

### DETAILED DESCRIPTION OF DISCLOSED EMBODIMENTS

The disclosure may be understood by referring to the following detailed description with reference to the accompanying drawings. It is noted that for comprehension of the reader and simplicity of the drawings, in the drawings of the disclosure, only a part of the electronic device is shown, and specific elements in the drawings are not necessarily drawn to scale. Moreover, the quantity and the size of each element in the drawings are only schematic and are not intended to limit the scope of the disclosure.

In the following specification and claims, the terms “having”, “including”, etc. are open-ended terms, so they should be interpreted to mean “including but not limited to . . .”.

It should be understood that when an element or a film layer is described as being “on” or “connected to” another element or film layer, it may be directly on or connected to the another element or film layer, or there is an intervening element or film layer therebetween (i.e., indirect connection). Conversely, when an element or film layer is described as being “directly on” or “directly connected to” another element or film layer, there is no intervening element or film layer therebetween.

The terms such as “first”, “second”, “third”, etc. may be used to describe elements, but the elements should not be limited by these terms. The terms are only intended to distinguish an element from another element in the specification. It is possible that the claims do not use the same terms and replace the terms with “first”, “second”, “third” etc. according to the sequence declared in the claims. Accordingly, in the specification, a first element may be a second element in the claims.

In some embodiments of the disclosure, unless specifically defined, terms related to bonding and connection such as “connect”, “interconnect”, etc. may mean that two structures are in direct contact, or that two structures are not in direct contact and another structure is provided therebetween. The terms related to bonding and connection may also cover cases where two structures are both movable or two structures are both fixed. In addition, the term “couple” includes any direct and indirect electrical connection means.

In the disclosure, the length and width may be measured by an optical microscope, and the thickness may be measured based on a cross-sectional image in an electron microscope, but the disclosure is not limited thereto. In addition, there may be a certain error between any two values or directions used for comparison.

In this disclosure, the terms “approximately”, “about”, and “substantially” usually mean within 10%, 5%, 3%, 2%, 1%, or 0.5% of a given value or range. The quantity given here is an approximate quantity. That is, the meaning of “approximately”, “approximately”, and “substantially” may still be implied without specifying “approximately”, “about” or “substantially”. In addition, the term “a range is between a first value and a second value” means that the range includes the first value, the second value, and other values therebetween. In the disclosure, the electronic device may include a display device, an antenna device (such as a liquid crystal antenna), a sensing device, a light emitting display, a touch device, or a splicing device, but is not limited thereto. The electronic device may include a bendable or flexible electronic device. The shape of the electronic device may be rectangular, circular, polygonal, a shape with curved edges, or other suitable shapes. The display device may include, for example, a light emitting diode (LED), a liquid crystal, a fluorescence, a phosphor, a quantum dot (QD), other suitable materials, or a combination of the above, but is not limited thereto. The light emitting diode may include, for example, an organic light emitting diode (OLED), an inorganic light-emitting diode (LED), a mini LED, a micro LED or a quantum dot LED (e.g., QLED or QDLED), other suitable materials, or any combination of the above, but is not limited thereto. The display device may include, for example, a splicing display device, but is not limited thereto. The antenna device may include, for example, a liquid crystal antenna, but is not limited thereto. The antenna device may include, for example, an antenna splicing device, but is not limited thereto. It is noted that the electronic device may be any combination of the above, but is not limited thereto. In addition, the shape of the electronic device may be rectangular, circular, polygonal, a shape with curved edges, or other suitable shapes. The electronic device may have peripheral systems such as a driving system, a control system, a light source system, a rack system, etc. to support a display device, an antenna device, or a splicing device. Hereinafter, a display device will be described to illustrate the content of the disclosure, but the disclosure is not limited thereto.

In the disclosure, the features in multiple different embodiments descried below may be replaced, combined, and/or mixed to form other embodiments without departing from the spirit of the disclosure. The features of the embodiments may be arbitrarily mixed and combined as long as they do not depart from or conflict with the spirit of the disclosure.

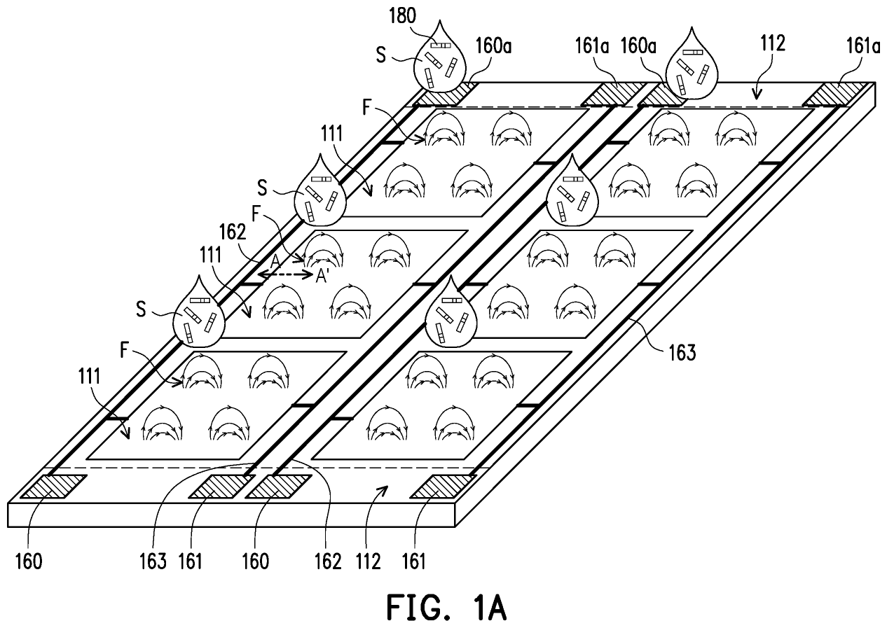

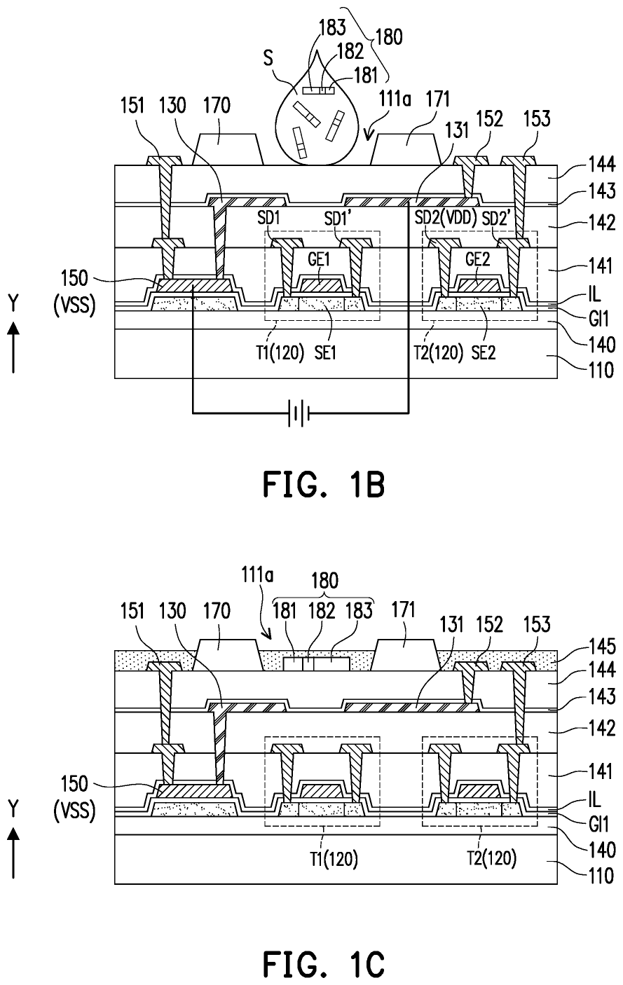

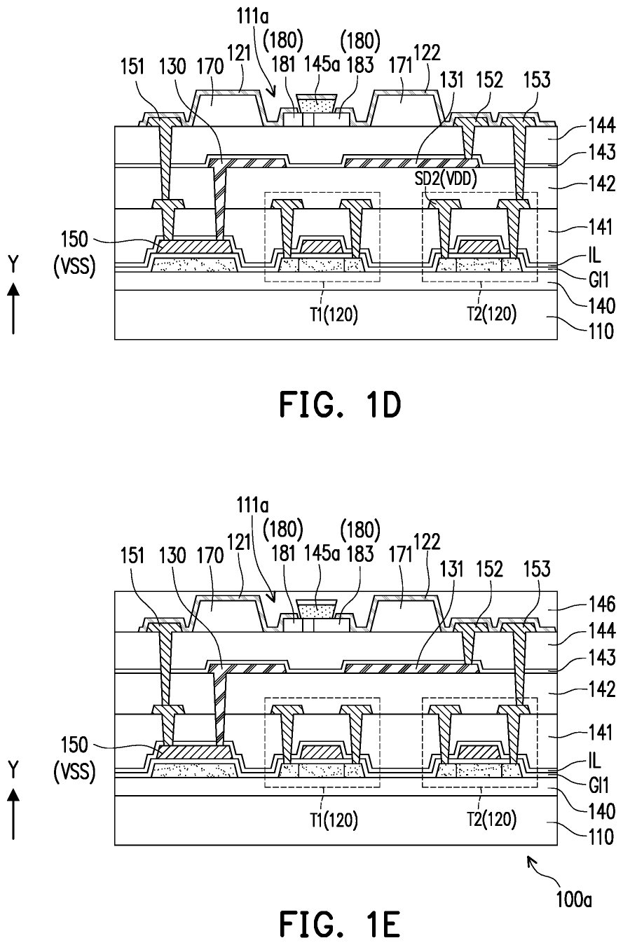

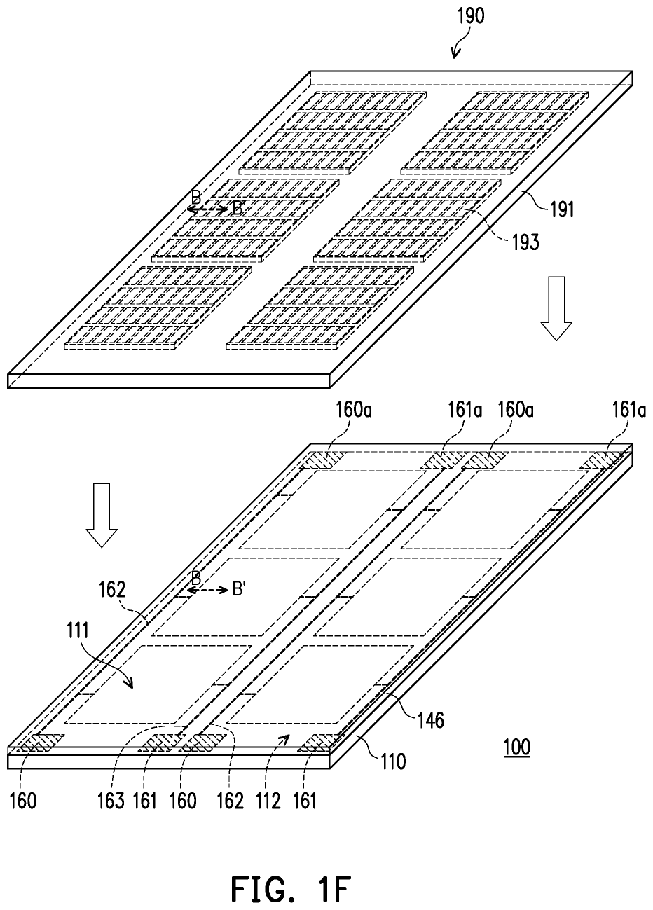

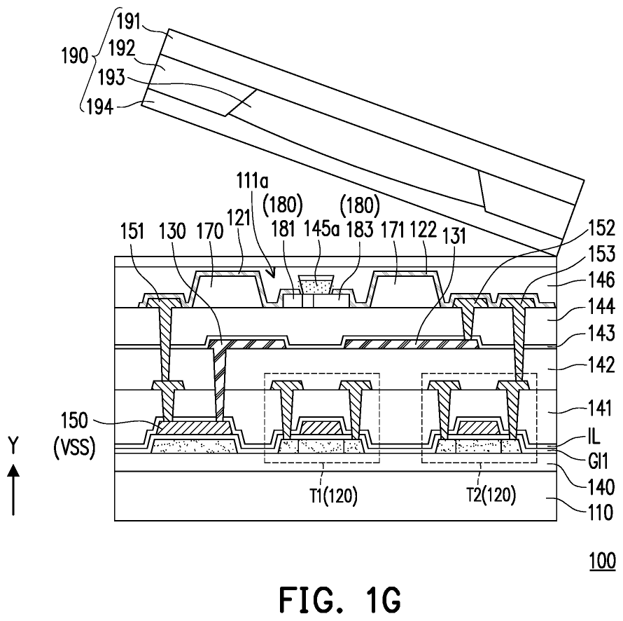

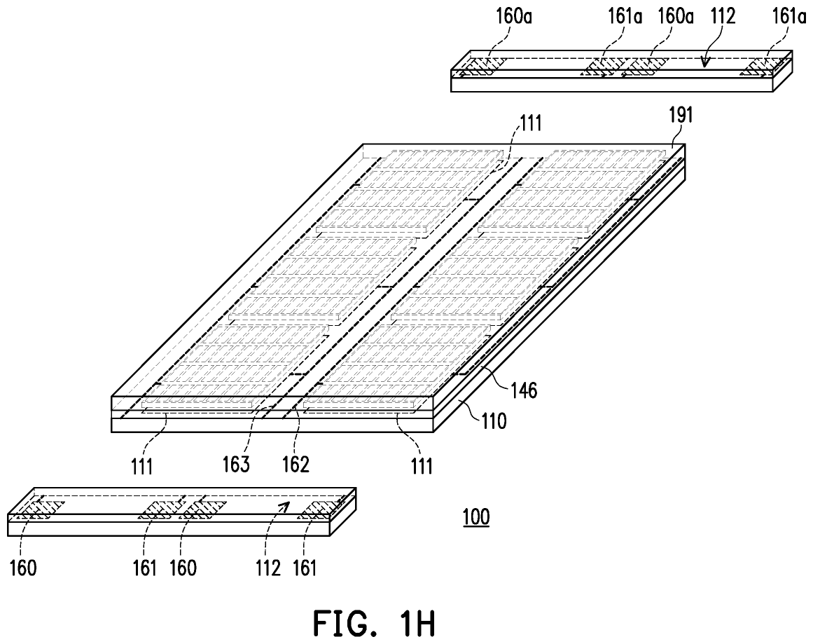

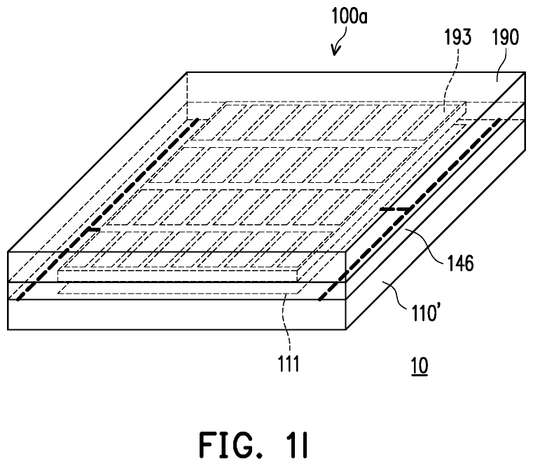

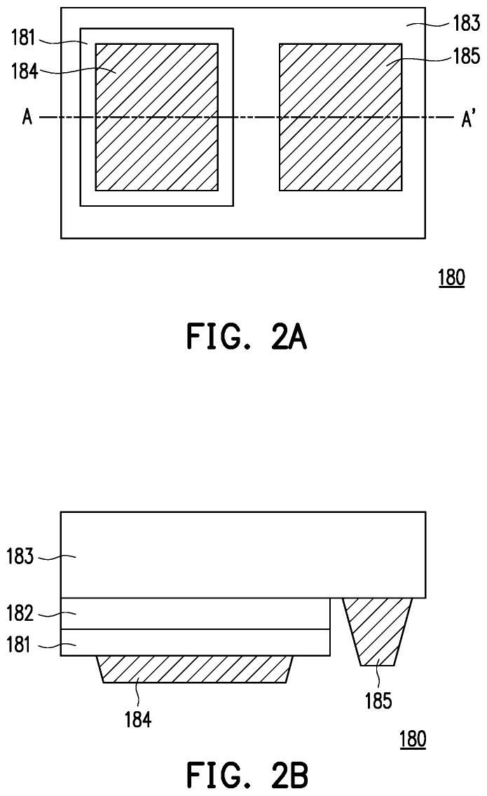

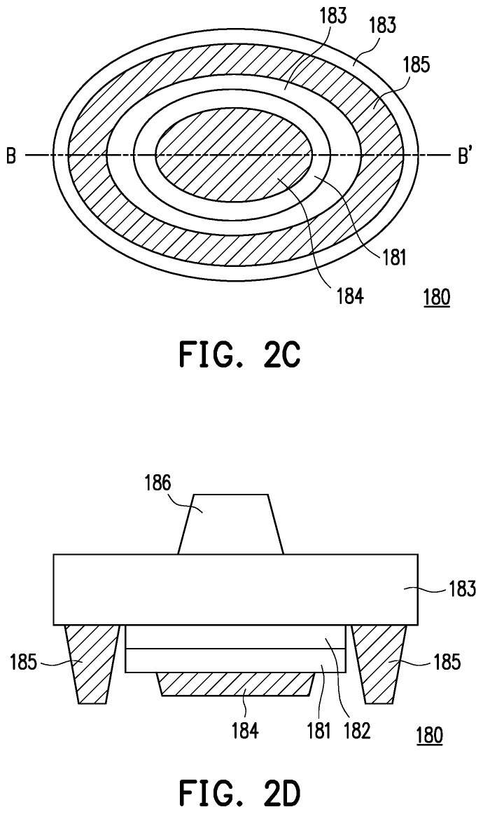

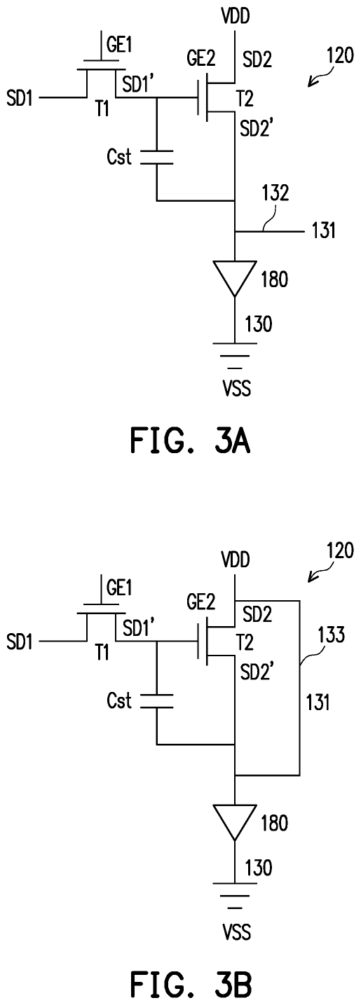

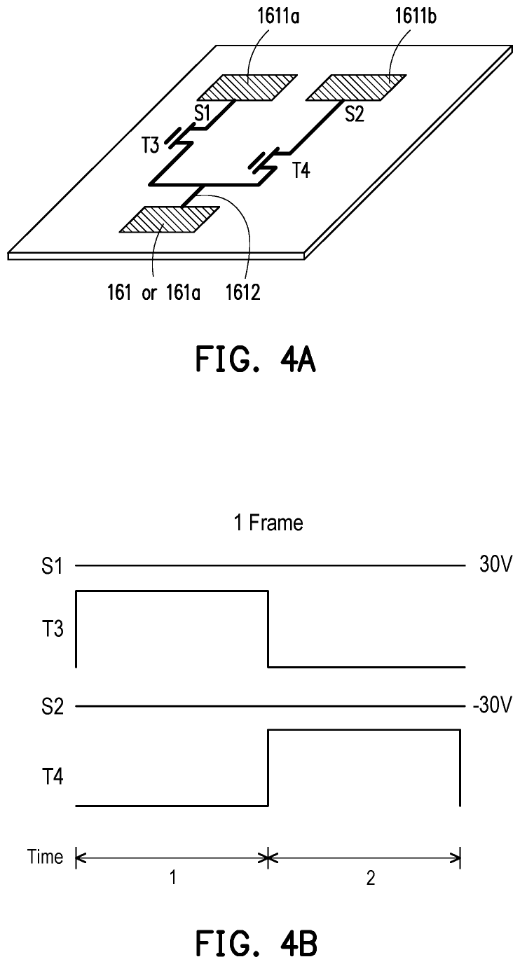

FIG. 1A to FIG. 1I are schematic top diagrams or schematic cross-sectional diagrams of a manufacturing method of a display device according to some embodiments of the disclosure. FIG. 1B is a schematic cross-sectional diagram of a display device of FIG. 1A along a section line A-A′. FIG. 1G is a schematic cross-sectional diagram of a display device of FIG. 1F along a section line B-B′. For clarity of the drawings and convenience of description, some elements of a liquid crystal panel 110 and a display device 10 are not shown in FIG. 1A, FIG. 1F, FIG. 1H, and FIG. if FIG. 2A and FIG. 2B are respectively a schematic bottom diagram and a schematic cross-sectional diagram of a light emitting element according to some embodiments of the disclosure. FIG. 2C and FIG. 2D are respectively a schematic top diagram and a schematic cross-sectional diagram of a light emitting element according to some embodiments of the disclosure. FIG. 3A is a circuit diagram of a driving circuit of a display device according to some embodiments of the disclosure. FIG. 3B is a circuit diagram of a driving circuit of a display device according to some embodiments of the disclosure. FIG. 4A is a schematic diagram of a generating method of an AC voltage according to some embodiments of the disclosure. FIG. 4B is a timing diagram of the generating method of an AC voltage of FIG. 4A.

Referring to FIG. 1A and FIG. 1B at the same time, in a manufacturing method of a display device 10 of this embodiment, first in Step 1, a substrate 110 is provided, and a driving circuit 120, a first alignment electrode 130, and a second alignment electrode 131 are formed on the substrate 110. In this embodiment, the substrate 110 may include a rigid substrate, a flexible substrate, or a combination of the above. For example, a material of the substrate 110 may include glass, quartz, sapphire, ceramic, polycarbonate (PC), polyimide (PI), polyethylene terephthalate (PET), other suitable substrate materials, or a combination of the above, but is not limited thereto. In this embodiment, the substrate 110 may be, for example, a large-sized substrate before cutting, but is not limited thereto. In an embodiment, the large-sized substrate may be used to manufacture multiple display devices thereon at the same time. In some embodiments, the size of the substrate 110 may be, for example, 1100 millimeters (mm)×1200 millimeters, or 1500 millimeters×1800 millimeters, but is not limited thereto. In other embodiments, the substrate 110 on which the driving circuit 120 has been formed may be provided, but is not limited thereto.

In addition, in this embodiment, the substrate 110 may have multiple pixel regions 111 and peripheral regions 112. For example, the pixel region 111 may be regarded as a predetermined position where a display region of the display device 10 will be formed later. The display region may include multiple pixels, and each of the pixels may include multiple sub-pixels, e.g., one or three sub-pixels, but is not limited thereto. The driving circuit 120 may be directly or indirectly disposed on the pixel region 111. The driving circuit 120 may be regarded as a pixel circuit of the display device 10, but is not limited thereto. The driving circuit 120 may include a transistor, a signal line, an electrode, a conductive pad, an active element, a passive element, other suitable circuit elements, or a combination of the above, but is not limited thereto. For example, the driving circuit 120 may include a transistor T1, a transistor T2, a capacitor Cst, a high power supply voltage Vdd (such as a power line, but is not limited thereto), and a low power supply voltage Vss (such as a ground line, but is not limited thereto), as shown in FIG. 3A and FIG. 3B, but is not limited thereto.

In an embodiment, as shown in FIG. 1B, after the substrate 110 is provided, a buffer layer 140 may be selectively formed on the substrate 110, but is not limited thereto. Next, a transistor T1, a transistor T2, a conductive pad 150, a gate insulation layer GI1, an insulation layer IL, and a dielectric layer 141 may be formed on the buffer layer 140. The transistor T1, the transistor T2, and the conductive pad 150 may be disposed in the pixel region 111. The transistor T1 may include a gate GE1, part of the gate insulation layer GI1, the insulation layer IL, a source SD1, a drain SD1′, and a semiconductor layer SE1, but is not limited thereto. The transistor T2 may include a gate GE2, part of the gate insulation layer GI1, the insulation layer IL, a source SD2, a drain SD2′, and a semiconductor layer SE2, but is not limited thereto. In this embodiment, a material of the semiconductor layers SE1 and SE2 may include amorphous silicon, low-temperature polysilicon (LTPS), metal oxide (such as indium gallium zinc oxide (IGZO)), other suitable materials or a combination of the above, but is not limited thereto. In other embodiments, different transistors may include different semiconductor layer materials. For example, in the driving circuit 120, the semiconductor layer of some transistors is a metal oxide, and the semiconductor layer of other transistors is a silicon semiconductor, but is not limited thereto. In addition, the transistors of the driving circuit 120 may include a bottom-gate type transistor, a top-gate type transistor, and/or a double-gate type transistor. For example, some of the transistors are bottom-gate type transistors, and others of the transistors are double-gate type transistors, but the disclosure is not limited thereto.

Next, a flat layer 142 may be formed on the transistor T1 and the transistor T2, so that the flat layer 142 covers the sources SD1 and SD2, the drains SD1′ and SD2′, and the dielectric layer 141. The flat layer 142 and the substrate 110 may be respectively disposed on two opposite sides of the transistors T1 and T2.

Next, the first alignment electrode 130 and the second alignment electrode 131 may be formed on the flat layer 142, and an insulation layer 143 and an insulation layer 144 may be formed on the first alignment electrode 130 and the second alignment electrode 131, but are not limited thereto. The first alignment electrode 130 and the second alignment electrode 131 are disposed in the pixel region 111. The insulation layer 143 covers the first alignment electrode 130, the second alignment electrode 131, and the flat layer 142, and the insulation layer 144 covers the insulation layer 143. The first alignment electrode 130 may be electrically connected to the conductive pad 150. In this embodiment, the buffer layer 140, the gate insulation layer GI1, the insulation layer IL, the dielectric layer 141, the flat layer 142, the insulation layer 143, and the insulation layer 144 may be single-layer structures or multi-layer structures, and may include, for example, an organic material, an inorganic material, or a combination of the above, but are not limited thereto.

Next, a conductive pad 151, a conductive pad 152, a conductive pad 153, multiple first alignment conductive pads 160 and 160a, multiple second alignment conductive pads 161 and 161a, a first alignment circuit 162, a second alignment circuit 163, a barrier 170, and a barrier 171 are formed on the insulation layer 144. In some embodiments, the conductive pad may include a bonding pad, but is not limited thereto. The conductive pad 151, the conductive pad 152, and the conductive pad 153 are disposed in the pixel region 111. The first alignment conductive pad 160 and the second alignment conductive pad 161 are disposed in the peripheral region 112 on one side of the substrate 110, and the first alignment conductive pad 160a and the second alignment conductive pad 161a are disposed in the peripheral region 112 on another side of the substrate 110. The conductive pad 151 may be electrically connected to the conductive pad 150. The conductive pad 152 may be electrically connected to the second alignment electrode 131, and the conductive pad 153 may be electrically connected to the drain SD2′ of the transistor T2. The first alignment conductive pads 160 and 160a may be electrically connected to the first alignment circuit 162 and be electrically connected to the conductive pad 150 and the first alignment electrode 130 through the first alignment circuit 162. In this embodiment, the same signal may be applied through the first alignment conductive pads 160 and 160a to improve the signal uniformity. The second alignment conductive pads 161 and 161a may be electrically connected to the second alignment circuit 163 and be electrically connected to the second alignment electrode 131 through the second alignment circuit 163. In this embodiment, the same signal may be applied through the second alignment conductive pads 161 and 161a to improve the signal uniformity. The barrier 170 and the barrier 171 may be disposed respectively corresponding to the first alignment electrode 130 and the second alignment electrode 131. That is to say, the barrier 170 may overlap the first alignment electrode 130 in a normal direction Y of the substrate 110, and the barrier 171 may overlap the second alignment electrode 131 in the normal direction Y of the substrate 110. In addition, as shown in FIG. 1B, a light emitting element mounting region 111a may be located between the barrier 170 and the barrier 171, and may be located on the insulation layer 144. In this embodiment, the light emitting element mounting region 111a in one sub-pixel may accommodate multiple light emitting elements 180, and the number of light emitting elements 180 in one sub-pixel may range from 3 to 50, e.g., 5, 10, 20, or 30, but is not limited thereto. In other embodiments, the light emitting element mounting region 111a has an accommodating space that may accommodate at least one light emitting element 180. In some embodiments, the light emitting element mounting region 111a may form a closed accommodating space on the insulating layer 144 (not shown), and surroundings of the closed accommodating space are formed by the barriers (like a pit from the top view). For example, the barrier 170 and the barrier 171 as in FIG. 1B may be disposed on the left and right sides of the closed accommodating space. In addition, a front barrier and a rear barrier (not shown) are connected to the barrier 170 and the barrier 171 to form a closed accommodating space (not shown), which may accommodate multiple light emitting elements 180. In other embodiments, the closed accommodating space may accommodate at least one light emitting element 180. The above process of forming the driving circuit 120 is an exemplary embodiment of the disclosure, and those skilled in the art may omit some steps or add other steps to form other embodiments of the disclosure.

Continuing to refer to FIG. 1A and FIG. 1B, in Step 2, the light emitting element 180 is placed in the pixel region 111. For example, after the light emitting element 180 is placed, an orthographic projection of the light emitting element 180 in the normal direction Y of the substrate 110 may overlap an orthographic projection of the pixel region 111 in the normal direction Y of the substrate 110. In this disclosure, if not specifically stated, “overlap” may include complete overlapping and partial overlapping. In an embodiment, the light emitting elements 180 may be placed in multiple light emitting element mounting regions 111a of the pixel region 111 by, for example, an inkjet printing process. For example, the light emitting elements 180 are first mixed with a solvent to form a solution S, where the light emitting elements 180 in the solution S may be arranged in a disorderly (or non-directional) manner. In this embodiment, the solvent may include water and/or an organic solvent, but is not limited thereto. The organic solvent may include alcohol, toluene, acetone, ethanol, ether, methylene chloride, other organic solvents that are volatile at a low temperature (such as 30° C. to 85° C., but is not limited thereto), or a combination of the above, but is not limited thereto. Next, the solution S may be dripped or poured into the light emitting element mounting regions 111a by the ink-jet printing process, so that the light emitting element mounting regions 111a may include the light emitting elements 180. In some embodiments, the light emitting elements 180 dripped or poured into the solution S of the light emitting element mounting regions 111a may be too far away from the first alignment electrode 130 and the second alignment electrode 131, resulting in problems of low electric field intensity and insufficient pull force/push force for the alignment. Therefore, before an electric field F is applied to align the light emitting elements 180, the solution S may be pre-baked to reduce the volume of the solution S, so that the light emitting elements 180 may be closer to the first alignment electrode 130 and the second alignment electrode 131. In this way, the light emitting elements 180 may be more easily aligned or closer to a fixed position in an environment with high electric field intensity. For example, the time of the pre-baking process may be one second to several minutes, e.g., one minute, and the disclosure is not limited thereto.

In the manufacturing method of the display device 10 of this embodiment, the solution S is dripped or poured into the light emitting element mounting region 111a before the electric field F is applied to align the light emitting elements 180, so as to achieve an effect of power saving. However, the disclosure does not limit the timing of applying the electric field. That is to say, in some embodiments, the electric field F may also be applied before the solution S is dripped or poured into the light emitting element mounting region 111a, so that the light emitting elements 180 in the solution S may be aligned using the pull force and/or the push force of the electric field F while being dripped or poured into the light emitting element mounting region 111a, so as to reduce the precipitation and stacking, and thus failure to align (turn), of the light emitting elements 180 resulting from excessive light emitting elements 180 in the solution S, but the disclosure is not limited thereto.

In this embodiment, the light emitting element 180 may include a bar LED, a wedge-shaped LED (as shown in FIG. 2A and FIG. 2B), and a concentric LED (as shown in FIG. 2C and FIG. 2D), but is not limited thereto. In this embodiment, the light emitting element 180 may have a first type semiconductor layer 181, a light emitting layer 182, and a second type semiconductor layer 183. The first type semiconductor layer 181 may be a P type semiconductor layer, and the second type semiconductor layer 183 may be an N type semiconductor layer, but the disclosure is not limited thereto. In some embodiments, the first type semiconductor layer may also be an N type semiconductor layer, and the second type semiconductor layer may also be a P type semiconductor layer. In this embodiment, a length of a long axis of the bar-shaped light emitting element 180 may be, for example, 3 micrometers (μm) to 4 micrometers, and a length of a short axis may be less than 1 micrometer, but the disclosure is not limited thereto. In some embodiments, the length of the short axis of the light emitting element may also be, for example, tens of nanometers (nm) to hundreds of nanometers. In this embodiment, a contour of the light emitting element 180 in a view facing the short axis may be square, hexagonal, circular, or other suitable shapes, but is not limited thereto. In some embodiments, the wedge-shaped LED may include a first type semiconductor layer 181, a light emitting layer 182, a second type semiconductor layer 183, and conductive pads 184 and 185, as shown in FIG. 2A and FIG. 2B. In some embodiments, the concentric LED may include a first type semiconductor layer 181, a light emitting layer 182, a second type semiconductor layer 183, conductive pads 184 and 185, and a pillar 186, as shown in FIG. 2C and FIG. 2D.

Referring to FIG. 1A to FIG. 1C, in Step 3, the electric field F is applied to align the light emitting elements 180. Specifically, in this embodiment, a common voltage may be transmitted to the first alignment electrode 130 through the first alignment conductive pads 160 and 160a, the first alignment circuit 162, and the conductive pad 150. An alternating current (AC) voltage or a direct current (DC) voltage may be transmitted to the second alignment electrode 131 through the second alignment conductive pads 161 and 161a, and the second alignment circuit 163. Since the first alignment electrode 130 and the second alignment electrode 131 may be adjacent to the light emitting element mounting region 111a, and there is a voltage difference between the common voltage transmitted to the first alignment electrode 130 and the AC voltage or the DC voltage transmitted to the second alignment electrode 131, the electric field F is generated between the first alignment electrode 130 and the second alignment electrode 131, and the pull force and/or push force of the electric field F may align the light emitting elements 180 in the solution S, so that the aligned light emitting elements 180 are arranged in a substantially ordered (or directional) manner. That is to say, the light emitting elements 180 may be substantially aligned in one direction or arranged in one direction. For example, long axis directions of the two light emitting elements 180 may be approximately within 0 to 60 degrees. In this embodiment, the first type semiconductor layer 181 of the aligned light emitting element 180 may substantially face toward the first alignment electrode 130, and the second type semiconductor layer 183 may substantially face toward the second alignment electrode 131, as shown in FIG. 1C, but the disclosure is not limited thereto. In some embodiments, the first type semiconductor layer 181 of the aligned light emitting element 180 may also substantially face toward the second alignment electrode 131, and the second type semiconductor layer 183 may substantially face toward the first alignment electrode 130. In other embodiments, in one light emitting element mounting region 111a, the light emitting elements 180 are substantially aligned in one direction or arranged in one direction, but the first type semiconductor layer 181 of some of the light emitting elements 180 may substantially face toward the first alignment electrode 130, and the second type semiconductor layer 183 of some of the light emitting elements 180 may substantially face toward the first alignment electrode 130, but the disclosure is not limited thereto. In addition, in some embodiments, an electric field emission device may also be used to apply an electric field, so as to align the light emitting elements 180.

In addition, in this embodiment, the method shown in FIG. 3A or FIG. 3B may be adopted to prevent the common voltage transmitted to the first alignment electrode 130 from passing through the transistor T1 and the transistor T2, and to prevent the AC voltage or the DC voltage transmitted to the second alignment electrode 131 from passing through the transistor T1 and the transistor T2, thereby reducing the risk of damage or failure of the transistor T1 and the transistor T2 when the AC voltage or the DC voltage transmitted to the second alignment electrode 131 is a high voltage. For example, as shown in FIG. 3A, a node may be configured between the drain SD2′ of the transistor T2 and the light emitting element 180, and the node is electrically connected to the second alignment electrode 131, thereby reducing the probability for the AC voltage or the DC voltage transmitted to the second alignment electrode 131 to pass through the transistor T1 and/or the transistor T2. In some embodiments, the node may be electrically connected to the second alignment electrode 131 through at least one conductive line (such as a conductive line 132), but the disclosure is not limited thereto. As shown in FIG. 3B, a node may be configured between the high power supply voltage Vdd and the source SD2 of the transistor T2, so that the node is electrically connected to another node between the drain SD2′ of the transistor T2 and the light emitting element 180, thereby reducing the probability for the AC voltage or the DC voltage transmitted to the second alignment electrode 131 to pass through the transistor T1 and/or the transistor T2 by a crossover. In some embodiments, the nodes may be electrically connected to each other through at least one conductive line (such as a conductive line 133), but the disclosure is not limited thereto.

In this embodiment, as shown in FIG. 1A, the substantially same common voltage signals may be respectively transmitted from the first alignment conductive pad 160 and the first alignment conductive pad 160a located on two sides of the substrate 110 through the same first alignment circuit 162 to the first alignment electrode 130. On another side, the substantially same AC voltage signals (or the DC voltage signals) may be respectively transmitted from the second alignment conductive pad 161 and the second alignment conductive pad 161a located on two sides of the substrate 110 through the same second alignment circuit 163 to the second alignment electrode 131. The two signals may form the electric field F in the light emitting element mounting region 111a. Therefore, the light emitting element mounting region 111a in the pixel region 111 may receive an electric field F that is more stable and has uniform intensity, so that the light emitting elements of the pixel region 111 may be arranged in a more orderly manner. Therefore, the subsequently aligned light emitting elements 180 can be electrically connected to the driving circuit 120 through a first connection circuit 121 and a second connection circuit 122, thereby improving the light-emitting ratio of the light emitting elements in the pixel region 111.

In this embodiment, a switching element (not shown) may be selectively disposed between the first alignment circuit 162 and the light emitting element mounting region 111a (and/or between the second alignment circuit 163 and the pixel region 111). In this way, the switching element may be used to control in which pixel regions 111 the voltage signals of the first alignment conductive pads 160 and 160a (and/or the second alignment conductive pads 161 and 161a) will enter the first alignment electrode 130 (and/or the second alignment electrode 131), and control in which pixel regions 111 the voltage signals of the first alignment conductive pads 160 and 160a (and/or the second alignment conductive pads 161 and 161a) will not enter the first alignment electrode 130 (and/or the second alignment electrode 131).

In this embodiment, the voltage signals may be applied to the first alignment conductive pads 160 and 160a (or the first alignment electrode 130) and the second alignment conductive pads 161 and 161a (or the second alignment electrode 131) by, for example, the following different signal generating methods, but the disclosure is not limited thereto. For example, in a signal generating method 1, a DC voltage of 0 volts may be applied to the first alignment conductive pads 160 and 160a (or the first alignment electrode 130), and a DC voltage, such as a DC voltage of 30 volts, may be applied to the second alignment conductive pads 161 and 161a (or the second alignment electrode 131), to generate a voltage difference (such as 30 volts) and form a unidirectional electric field F. In this way, the pull force or the push force of the electric field F may be used to align the light emitting elements 180.

In a signal generating method 2, a DC voltage of, for example, 0 volts, may be applied to the first alignment conductive pads 160 and 160a (or the first alignment electrode 130), and an AC voltage is applied to the second alignment conductive pads 161 and 161a (or the second alignment electrode 131). The AC voltage may be, for example, +30 volts and −30 volts (for example, +30 volts are applied at a first time point and −30 volts are applied at a second time point in alternation, but the disclosure is not limited thereto), so as to generate a voltage difference of 30 volts at different time points and form a forward electric field F or a reverse electric field F. In this way, the pull force and push force of the alternating electric field F may be used to align (turn) the light emitting elements 180 more easily through vibration.

In a signal generation method 3, an AC voltage of, for example, +15 volts and −15 volts, may be applied to the first alignment conductive pads 160 and 160a (or the first alignment electrode 130), and an AC voltage of, for example, +15 volts and −15 volts, may be applied to the second alignment conductive pads 161 and 161a (or the second alignment electrode 131), (for example, at the first time point, +15 volts may be applied to the first alignment conductive pads 160 and 160a, and −15 volts may be applied to the second alignment conductive pads 161 and 161a; at the second time point, −15 volts may be applied to the first alignment conductive pads 160 and 160a, and +15 volts may be applied to the second alignment conductive pads 161 and 161a, but the disclosure is not limited thereto), so as to generate a voltage difference of 30 volts at different time points and form a forward electric field F or a reverse electric field F. In this way, the pull force and push force of the alternating electric field F may be used to align (turn) the light emitting elements 180 more easily through vibration while achieving the effect of power saving. The voltage levels in the signal generating methods 1 to 3 are only examples provided for convenience of illustration, and the voltage levels may be adjusted according to the actual requirements.

In addition, referring to FIG. 4A and FIG. 4B, in this embodiment, the AC voltage generating methods in the signal generating method 2 and the signal generating method 3 may be achieved by, for example, electrically connecting two DC voltage signals S1, S2 and two corresponding transistors T3 and T4 to the corresponding alignment conductive pads, but are not limited thereto. Taking the second alignment conductive pad 161 or the second alignment conductive pad 161a in FIG. 1A as an example for illustration, specifically, the design as shown in FIG. 4A may be configured beside the second alignment conductive pad 161 or the second alignment conductive pad 161a. For example, a first signal endpoint 1611a, a second signal endpoint 1611b, a signal connection line 1612, the transistor T3, and the transistor T4 may be disposed, so that the DC voltage signal Si provided by the first signal endpoint 1611a may be electrically connected to the signal connection line 1612 through the transistor T3, and that the DC voltage signal S2 provided by the second signal endpoint 1611b may be electrically connected to the signal connection line 1612 through the transistor T4. Next, the DC voltage signal S1 continuously provides a positive voltage (such as +30 volts), and the DC voltage signal S2 continuously provides a negative voltage (such as −30 volts). Furthermore, the transistor T3 and the transistor T4 may be switch on and off alternately at different time points, so as to enable the second alignment conductive pad 161 to stimulate an AC voltage and provide voltages of, for example, +30 volts and −30 volts respectively at different time points to the second alignment circuit 163 and the second alignment electrode 131. More specifically, as shown in FIG. 4A, at the first time point, the transistor T3 is switched on and the transistor T4 is switched off at the same time, so that the DC voltage signal Si may be transmitted to the second alignment conductive pad 161 (shown in FIG. 1A) or the second alignment conductive pad 161a, and the DC voltage signal S2 may not be transmitted to the second alignment conductive pad 161 or the second alignment conductive pad 161a. At the second time point, the transistor T3 may be switched off and the transistor T4 may be switched on at the same time, so that the DC voltage signal S1 may not be transmitted to the second alignment conductive pad 161 or the second alignment conductive pad 161a, and the DC voltage signal S2 may be transmitted to the second alignment conductive pad 161 or second alignment conductive pad 161a. In this way, the second alignment conductive pad 161 or the second alignment conductive pad 161a may provide a voltage of, for example, +30 volts, to the second alignment circuit 163 and the second alignment electrode 131 at the first time point, and provide a voltage of, for example, −30 volts to the second alignment circuit 163 and the second alignment electrode 131 at the second time point by simulating the AC voltage. In some embodiments, the signal connection line 1612 may also be directly electrically connected to the second alignment circuit 163 in FIG. 1A without passing through the second alignment conductive pad 161 or the second alignment conductive pad 161a, and may also simulate an AC voltage by, for example, providing a voltage of +30 volts to the second alignment circuit 163 and the second alignment electrode 131 at the first time point, and providing a voltage of −30 volts to the second alignment circuit 163 and the second alignment electrode 131 at the second time point.

In an embodiment, before the electric field F is applied to align the light emitting elements 180 in Step 3, the orderly arranged light emitting elements 180 in the solution S may be selectively baked first, so that the solvent in the solution S is completely volatilized, and the orderly arranged light emitting elements 180 are substantially positioned on the insulation layer 144, but the disclosure is not limited thereto. In this embodiment, during the baking process, the first alignment electrode 130 and the second alignment electrode 131 may be continuously provided with the voltage (including the DC voltage and/or the AC voltage, but are not limited thereto), so as to reduce the probability for the orderly arranged light emitting elements 180 to become disorderly arranged due to the disturbance when the solvent is volatilized. In some embodiments, the voltage continuously provided to the first alignment electrode 130 and the second alignment electrode 131 may be the DC voltage only, or a DC voltage converted from the AC voltage, thereby reducing the probability for the orderly arranged light emitting elements 180 to become disorderly arranged due to the staggered disturbance of the electric field.

Continuing to refer to FIG. 1D, in Step 4, the aligned light emitting elements 180 are electrically connected to the driving circuit 120. For example, in this embodiment, the first connection circuit 121 and the second connection circuit 122 may be formed on the insulation layer 144, so that the aligned light emitting elements 180 may be electrically connected to the driving circuit 120. The method of electrically connection may include depositing conductive materials, spot welding with conductive lines, or any other method that can electrically connect the aligned light emitting elements 180 to the driving circuit 120, and the disclosure is not limited thereto. In an embodiment, the first connection circuit 121 may cross the barrier 170 to connect the conductive pad 151 and part of the first type semiconductor layer 181 of the light emitting element 180 exposed from an insulation layer 145a. The second connection circuit 122 may cross the barrier 171 to connect the conductive pad 152, the conductive pad 153, and part of the second type semiconductor layer 183 of the light emitting element 180 exposed from the insulation layer 145a. In this way, the high power supply voltage Vdd may be electrically connected to the light emitting elements 180 through the transistor T2, the conductive pad 153, and the second connection circuit 122, and the light emitting elements 180 may be electrically connected to the low power supply voltage Vss through the first connection circuit 121, the conductive pad 151, and the conductive pad 150, as shown in FIG. 3A and FIG. 3B. There may be multiple light emitting elements 180 in the light emitting element mounting region 111a, and in some embodiments, the “alignment” in the disclosure may mean electrically connecting to the driving circuit 120 in the subsequent manufacturing process, and the long axis of the light emitting element 180 (or the light emitting element 180 does not necessarily have a long axis) may not necessarily be aligned in a specific direction. The first connection circuit 121 and the second connection circuit 122 may be made by the same process and disconnected by the topography of the insulation layer 145a, or may be made in separate processes. In this embodiment, a material of the first connection circuit 121 and the second connection circuit 122 may include a transparent conductive material, such as indium tin oxide, indium zinc oxide, indium oxide, zinc oxide, tin oxide, other suitable transparent conductive materials, or a combination of the above, but is not limited thereto.

Referring to FIG. 1C, in an embodiment, before the aligned light emitting elements 180 are electrically connected to the driving circuit 120 in Step 4, the aligned light emitting elements 180 may be selectively fixed. For example, in this embodiment, an insulation layer 145 may be formed on the aligned light emitting elements 180 first, so that the insulation layer 145 may at least partially cover the insulation layer 144, the conductive pad 151, the light emitting elements 180, the conductive pad 152, and the conductive pad 153, as shown in FIG. 1C. Next, the insulation layer 145 may be patterned, so that the patterned insulation layer 145a may expose part of the insulation layer 144, the conductive pad 151, part of the first type semiconductor layer 181, part of the second type semiconductor layer 183, the conductive pad 152, and/or the conductive pad 153, and the patterned insulation layer 145a may still fix the aligned light emitting elements 180, so that the aligned light emitting elements 180 may not shake, but the disclosure is not limited thereto. In some embodiments, the light emitting elements 180 may be fixed in other ways, such as using magnetic force or using a solvent of which the viscosity may change, but the disclosure is not limited thereto.

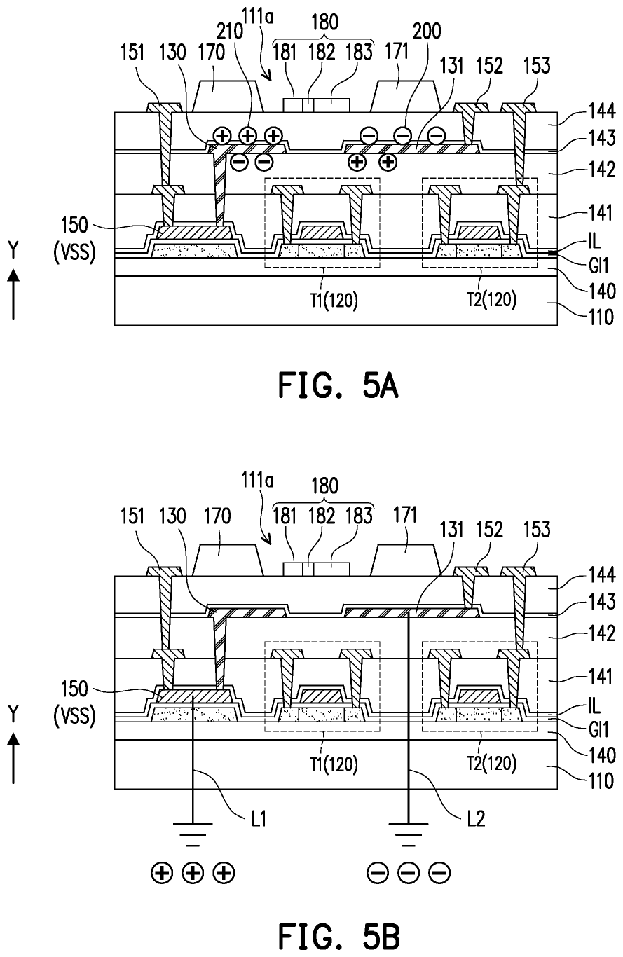

FIG. 5A and FIG. 5B are schematic cross-sectional diagrams of part of a manufacturing method of a display device according to some embodiments of the disclosure. The embodiment shown in FIG. 5A and FIG. 5B is similar to the embodiment shown in FIG. 1A to FIG. 1I, so the description for the same and similar elements in the two embodiments is omitted here. In the manufacturing method of the embodiment shown in FIG. 5A and FIG. 5B, before the aligned light emitting elements 180 are fixed, a step of discharging may be selectively performed.

For example, when the light emitting elements 180 are aligned, electrons 200 or holes 210 may be accumulated in the flat layer 142, the insulation layer 143, and the insulation layer 144 adjacent to the first alignment electrode 130 and the second alignment electrode 131, as shown in FIG. 5A. Therefore, the step of discharging may be used to remove the electrons 200 or the holes 210. For example, through a conductive line L1 connected to the conductive pad 150 and a conductive line L2 connected to the second alignment electrode 131, the electrons 200 or the holes 210 accumulated in the flat layer 142, the insulation layer 143, and the insulation layer 144 may be transferred to a ground or a low voltage, as shown in FIG. 5B. In this way, the problems of abnormal potential or mura resulting from the accumulation of the electrons 200 or the holes 210 are reduced.

Referring to FIG. 1E and FIG. 1F, in Step 5, the substrate 110 is packaged. For example, in this embodiment, an insulation layer 146 may be formed on the first connection circuit 121 and the second connection circuit 122, so that the insulation layer 146 may cover the insulation layer 144, the first connection circuit 121, the insulation layer 145a, the second connection circuit 122, the first alignment conductive pads 160 and160a, the second alignment conductive pads 161 and 161a, the first alignment circuit 162, and the second alignment circuit 163. In some embodiments, the insulation layer 146 may completely cover the substrate 110. In this embodiment, the insulation layer 145 and the insulation layer 146 may be single-layer structures or multi-layer structures, and may include, for example, an organic material, an inorganic material, or a combination of the above, but are not limited thereto.

Referring to FIG. IF and FIG. 1G, in some embodiments, the packaged substrate 110 may be paired with a color filter 190 in Step 6. For example, in this embodiment, the color filter 190 may include a substrate 191, a light shielding layer 192, a color conversion layer 193, and/or a protective layer 194, but is not limited thereto. The light shielding layer 192 and the color conversion layer 193 may be disposed on the substrate 191, and the protective layer 194 may be disposed on the light shielding layer 192 and the color conversion layer 193. The light shielding layer 192 may include a black matrix layer, but is not limited thereto. The color conversion layer 193 may include a quantum dot, a fluorescence, a phosphor, a color filter layer, other suitable color conversion materials, or a combination of the above, but is not limited thereto. In this embodiment, the color filter 190 may be paired with the packaged substrate 110 through an adhesive (not shown), but the disclosure is not limited thereto. The adhesive may be, for example, a sealant or a transparent adhesive. The sealant may be disposed between the color filter 190 and the substrate 110 and may be disposed corresponding to the peripheral region 112 of the substrate 110 and/or corresponding to the light shielding layer 192 of the color filter 190. For example, a light absorbing material may be mixed in the adhesive to reduce light leakage, and an insulation material may also be mixed in the adhesive to stabilize the adhesive and maintain a distance between the color filter 190 and the substrate 110. In some embodiments, the color filter 190 may also be paired with the packaged substrate 110 through, for example, the transparent adhesive (not shown). The transparent adhesive may be disposed as a whole layer between the color filter 190 and the substrate 110. The transparent adhesive may include an optically clear adhesive (OCA) or an optical clear resin (OCR), but is not limited thereto. In addition, the transparent adhesive corresponding to the peripheral region 112 of the substrate 110 may be etched to form an insulation layer (not shown), so as to increase the stability of the color filter 190 and the packaged substrate 110 after pairing. In some embodiments, the packaged substrate 110 may be cut before being paired with the color filter 190.

Referring to FIG. 1H and FIG. 1I, in Step 7, the substrate 110 carrying the aligned light emitting elements 180 may be cut into multiple sub-substrates 110′. For example, in this embodiment, portions of a display panel 100 corresponding to the peripheral region 112 of the substrate 110 may be cut off first. For example, the first alignment conductive pads 160 and 160a, and the second alignment conductive pads 161 and 161a are cut off, as shown in FIG. 1H. Next, portions of the display panel 100 corresponding to the pixel region 111 of the substrate 110 may be further cut to form multiple display panels 100a (including the sub-substrate 110′), as shown in FIG. 1I, but the disclosure is not limited thereto. In some embodiments, the display device 10 of this embodiment may be substantially completed so far, but the disclosure is not limited thereto.

In summary of the above, in the manufacturing method of the display device 10 in some embodiments of the disclosure, multiple display devices 10 may be manufactured in multiple pixel regions 111 on the large-sized substrate 110, and the manufacturing method includes the following steps. The light emitting elements 180 may be placed in multiple pixel regions 111. An electric field F may be applied in the pixel regions 111. The aligned light emitting elements 180 may be electrically connected to the driving circuit 120 in the pixel regions 111. The substrate 110 carrying the aligned light emitting elements 180 may be cut into multiple sub-substrates 110′. In other embodiments, other steps may be included. For example, the orderly arranged light emitting elements 180 in the solution S may be baked first. The light emitting elements 180 may be aligned in the pixel regions 111. The pixel regions 111 may be packaged. The pixel regions 111 may be paired with the color filter 190. In this way, the manufacturing method of the display device 10 in some embodiments of the disclosure may reduce the processing time, achieve mass production, or increase economic benefits. In addition, since the pixel regions 111 may receive the same common voltage signals and the same AC voltage signals (or DC voltage signals), the voltage difference and electric field intensity in the pixel regions 111 may be the same, thereby increasing the uniformity of the electric field or the alignment between the pixel regions 111.

Finally, it should be noted that the foregoing embodiments are merely used for describing the technical solutions of the disclosure, but are not intended to limit the disclosure. Although the disclosure has been described in detail with reference to the foregoing embodiments, a person of ordinary skill in the art should understand that modifications may still be made to the technical solutions in the foregoing embodiments, or equivalent replacements may be made to part or all of the technical features; and these modifications or replacements will not cause the essence of corresponding technical solutions to depart from the scope of the technical solutions in the embodiments of the disclosure.

What is claimed is:

1. A manufacturing method of a display device, comprising:
providing a substrate, wherein the substrate has a pixel region, and a driving circuit is disposed on the pixel region;
placing a light emitting element in the pixel region;
applying an electric field to align the light emitting element;
electrically connecting the aligned light emitting element to the driving circuit; and
cutting the substrate carrying the aligned light emitting element into a plurality of sub-substrates.

2. The manufacturing method according to claim 1, wherein the light emitting element is a light emitting diode in a bar shape.

3. The manufacturing method according to claim 1, further comprising:
a step of fixing the aligned light emitting element prior to electrically connecting the aligned light emitting element to the driving circuit.

4. The manufacturing method according to claim 1, wherein the light emitting element is placed in the pixel region by an inkjet printing process.
